(19) United States
(12) Patent Application Publication
(10) Pub. No.: US 2025/0258569 A1
(43) Pub. Date: Aug. 14, 2025

(54) VIRTUAL MOUSE

(71) Applicant: Architectronics Inc., New York, NY (US)

(72) Inventor: Stephen H. Lewis, New York, NY (US)

(73) Assignee: Architectronics Inc., New York, NY (US)

(21) Appl. No.: 19/195,901

(22) Filed: May 1, 2025

Related U.S. Application Data
(63) Continuation-in-part of application No. 18/520,614, filed on Nov. 28, 2023, now abandoned.
Application No. 18/520,614 is a continuation of application No. 17/727,843, filed on Apr. 25, 2022, now Pat. No. 11,868,569.
Application No. 17/727,843 is a continuation-in-part of application No. 17/069,986, filed on Oct. 14, 2020, now Pat. No. 11,340,710.

(51) Int. Cl. G06F 3/042; G06T 7/20; G06T 15/00

(52) U.S. Cl. CPC G06F 3/0423; G06T 7/20; G06T 15/00

(57) ABSTRACT

A gesture-based control system utilizes real-time camera input and artificial intelligence to interpret user hand gestures for controlling a digital interface. The system includes a camera and processor configured to analyze image data using machine learning models trained on a diverse set of stored hand gesture representations. Gestures are recognized based on positional attributes, handedness, and motion vectors, and are mapped to input commands such as swipe left, right, up, or down. The system is designed for simplicity, using natural, intuitive gestures, such as swiping, thumbs up, thumbs down, and the “OK” sign, requiring no memorization or complex training. These familiar motions enable touch-free navigation and interaction with digital content, including support for hierarchical menu structures. The system can operate with or without visual gesture feedback. Methods and non-transitory computer-readable media are also disclosed for performing gesture detection and command execution.

### CROSS-REFERENCE TO RELATED APPLICATIONS SECTION

This Application is a United States Continuation-in-part Patent Application of co-pending U.S. Non-Provisional patent application Ser. No. 18/520,614 filed on Nov. 28, 2023, which is a Continuation Patent Application and claims priority to U.S. Non-Provisional patent application Ser. No. 17/727,843, filed on Apr. 25, 2022, which issued as U.S. Pat. No. 11,868,569 on Jan. 9, 2024, which is a CIP Patent Application and claims priority to U.S. Non-Provisional patent application Ser. No. 17/069,986 filed on Oct. 14, 2020 and patented as U.S. Pat. No. 11,340,710 on May 24, 2022, which is a CIP Patent Application and claims priority to U.S. Non-Provisional application Ser. No. 15/617,811 filed on Jun. 8, 2017 and patented as U.S. Pat. No. 10,838,504 on Nov. 17, 2020, which claims priority to U.S. Provisional Patent Application Ser. No. 62/347,206 filed on Jun. 8, 2016, all of which are incorporated by reference herein in their entirety.

### FIELD OF THE EMBODIMENTS

This invention relates to a system for providing an interactive window display for individuals who are walking past a storefront display.

### BACKGROUND OF THE EMBODIMENTS

Glass-fronted stores on the street have been a feature of urban environments for centuries. As time has gone on, these displays have gotten larger, and have become more ubiquitous throughout retail. With this development of large plate glass surfaces, these displays, whether found on a storefront on a street, or in an indoor mall, have provided for a lot of direct communication between passersby and the store. Despite this golden opportunity to provide an interactive experience for passersby, the storefront remains a one-way street, displaying objects or images which a passerby can view, but not interact with. Given the explosion of computing devices making their way into many other industries, this lack of integration in the storefront seems puzzling.

There have been some isolated attempts to take advantage of this opportunity, that is, to exploit the opportunity to engage with a passerby. One way in which this is attempted is to place sensors outside the storefront window. These sensors are used to interpret user activity, and then provide an interactive experience. However, this approach results in the sensors being exposed to the elements, and leaves them vulnerable to vandalism. Further, there exist large technological and financial challenges with passing control data through or around the glass to interior computing devices, and the like.

Others have attempted to solve this problem by placing a special film on the inside of the glass and using a rear-projected image and capacitive or similar touch-sensing systems. While this seems like an attractive option, there are a number of drawbacks to this approach. First, users must physically touch the outside of the glass to engage the capacitive sensing technology. Further, the display image must be rear-projected onto the film, which is an inferior technology as the image quality suffers greatly and is adversely affected by sunlight and reflections on the glass itself. Moreover, the image cannot be displayed on a monitor which is inside the window, and is part of a closed system which is not connected to other aspects of the holistic window area, limiting the amount of interaction possible.

Examples of related art are described below:

E Display, Inc. offers a storefront window projection. The main element of this solution is a rear-projection film that can be mounted on any clear surface from inside to turn a store front window into a dynamic presentation screen. SSI Displays also offers a similar solution.

Screen Solutions International, through their website, offers another product where a transparent capacitive screen is attached to a controller. This screen may be retrofitted to a number of places, such as a television or window.

United States Patent Publication No.: 2016/0034108 pertains to system and method for operating a computer device using an interface device. The interface device includes at least one emitter of IR light/radiation with a peak intensity of between 780 nm and 1000 nm and at least one detector sensitive to IR light/radiation with a wavelength of 780 nm to 1000 nm wherein the user interface device is located adjacent to transparent, glass. The IR emitter directs IR radiation through the glass, wherein the IR radiation is reflected back through the glass to the IR detector and wherein the IR detector transforms the IR radiation into an electronic signal. The method includes the step of activating the detector from a front side of the glass. According to this implementation, the user must touch the glass directly.

None of the art described above addresses all of the issues that the present invention does.

Other solutions exist where a user's smartphone is used to control a standard screen set up in a window, however these solutions do not provide a responsive user interface where the user engages, directly and instantaneously, with their actions and the content on the screen.

### SUMMARY

A system for interacting with a screen without touching it, comprising a source of radiating energy directed into a predefined area, at least one directionally sensitive sensor that detects the radiation when it's reflected off of an object within the predefined area, and a processor that calculates position and motion information of the object and generates therefrom image information, which it sends to a screen where it is displayed.

### BRIEF DESCRIPTION OF THE DRAWINGS

The present disclosure may be better understood, and its numerous features and advantages made apparent to those skilled in the art, by referencing the accompanying drawings. The use of the same reference symbols in different drawings indicates similar or identical items.

FIG. 1 shows a side view of an interactive system, according to an embodiment of the present invention.

FIG. 2 is a rear perspective view of an interactive system while in use by a human user, according to an embodiment of the present invention.

FIG. 3 is a front perspective view of an interactive system, according to an embodiment of the present invention.

FIGS. 4A, 4B show front and side views of an interactive system, according to an embodiment of the present invention.

FIGS. 5A, 5B show front and side views of an interactive system, according to an embodiment of the present invention.

FIGS. 6A, 6B show front and side views of an interactive system, according to an embodiment of the present invention.

FIGS. 7A, 7B show front and perspective views of an interactive system, according to an embodiment of the present invention.

FIGS. 8A, 8B illustrate aspects of an interactive system, according to an embodiment of the present invention.

FIG. 9 illustrates aspects of an interactive system, according to an embodiment of the present invention.

FIG. 10 is a block diagram illustrating an example gesture-based control system in accordance with embodiments of the present disclosure.

FIG. 11 is a block diagram that further illustrates components of the gesture-based control system of FIG. 10, in accordance with embodiments of the present disclosure.

FIG. 12 is a flowchart illustrating a computer-implemented method for controlling a digital interface using gesture recognition, in accordance with embodiments of the present disclosure.

FIG. 13 is a flowchart illustrating a computer-implemented method performed by a non-transitory computer-readable medium for gesture-based interaction with a digital interface, in accordance with embodiments of the present disclosure.

FIG. 14A is a front-elevation view of an example embodiment of a user performing a single-hand swipe to rotate a three-dimensional product image on a storefront smart display with a digital interface controlled by the gesture-based system, in accordance with embodiments of the present disclosure.

FIG. 14B is a perspective view of an example embodiment of a virtual-reality (VR) user issuing a thumbs-up confirmation gesture within an immersive headset environment with a digital interface controlled by the gesture-based system, in accordance with embodiments of the present disclosure.

FIG. 14C is a partial interior view of an example embodiment of a vehicle in which a driver executes a one-hand swipe toward an automotive display with a digital interface controlled by the gesture-based system, in accordance with embodiments of the present disclosure.

FIG. 14D is a front-elevation view of an example embodiment of a shopper selecting a point of interest on an interactive mall map by forming an “OK” gesture on a display with a digital interface controlled by the gesture-based system, in accordance with embodiments of the present disclosure.

### DETAILED DESCRIPTION

Embodiments of the present invention will now be described with reference to the drawings. Identical elements in the various figures are identified with the same reference numerals. The embodiments are provided by way of explanation of the present invention, which is not intended to be limited thereto. Rather, the scope of the invention is defined by the claims. In fact, those of ordinary skill in the art may appreciate upon reading the present specification and viewing the present drawings that various modifications and variations can be made thereto.

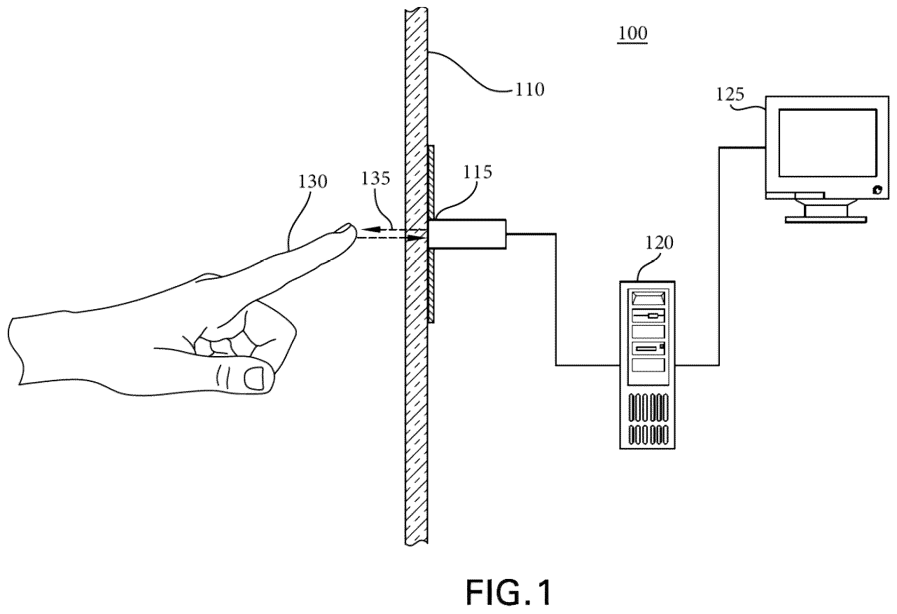

Referring now to FIG. 1, an interactive system 100 is illustratively depicted, in accordance with an embodiment of the present invention.

According to an embodiment, the system 100 includes a window or other transparent medium 110, visual sensors 115 located within the window 110, a computing device 120 coupled to the visual sensors 115, and a display screen 125 coupled to the computing device 120.

According to an embodiment, system permits users 130 who are outside a glass-fronted store window 110 to control images displayed on a computer screen 125 located on the side of the window 110 opposite the user 130. The users' 130 gestures and/or body movements are detected and interpreted by sensors. The sensors may be coupled to the window 110 and/or wholly located on the inside of the window 110.

According to an embodiment, the computing device 120 includes at least one processor and memory and is configured to execute a set of computer-readable instructions, which include instructions for controlling images on an external screen 125, and instructions for controlling at least one integrated object. According to an embodiment, the computing device includes at least one instruction, wherein the at least one instruction indicates to a user how to operate the system. According to an embodiment, the at least one movement of the at least one human appendage is associated with a particular instruction.

Depending on the desired configuration, the at least one processor may be of any type, including, but not limited to, a microprocessor (μP), a microcontroller (μC), and a digital signal processor (DSP), or any combination thereof. Further, the at least one processor may include one more levels of caching, such as a level cache memory, a processor core, and registers, among other examples. The processor core may include an arithmetic logic unit (ALU), a floating point unit (FPU), and/or a digital signal processing core (DSP Core), or any combination thereof. A memory controller may be used with the at least one processor, or, in some implementations, the memory controller may be an internal part of the memory controller.

Depending on the desired configuration, the system memory may be of any type, including, but not limited to, volatile memory (such as RA M), and/or non-volatile memory (such as ROM, flash memory, etc.), or any combination thereof. The system memory includes an operating system, one or more engines, and program data. In some embodiments, the one or more engines may be applications, software programs, services, or software platforms, as described infra. The system memory may also include a storage engine that may store any information disclosed herein.

In some embodiments, the gesture-based control system may include functionality for tracking and recording user interaction data to enable analytics related to user behavior, preferences, and/or engagement patterns. For example, the system may capture and log dwell time, defined as the duration for which a user focuses on and/or interacts with a particular visual element and/or digital object (e.g., hovering over a product image or pausing on a specific interface node). The system may also record the navigational path taken by the user through a network of content elements, which may include menu hierarchies, media sequences, interactive maps, or product displays. One or more interaction metrics may be stored in a local and/or remote database and/or compiled over time to generate an interest profile and/or behavioral map for a user. By analyzing these metrics, the system may derive interest vectors that reflect a topical preference, a visual focus tendency, and/or an interaction pattern. Such data may be used to optimize content layout, inform real-time content recommendations, personalize digital signage, and/or guide one or more iterations of the interface. In some embodiments, these insights may further support targeted advertising, heatmap generation, and consumer behavior analysis, enabling more efficient and/or user-centric system adaptation.

According to an embodiment, no sensors 115 and/or other equipment are positioned on the outside of the window 110 on the side of the window 110 in which the user 130 is positioned. This configuration enables users 130 to interact with the system 100 without touching the glass of the storefront window 110. In this way, the user 130 can move from “viewer” to “participant,” and engage in a more meaningful interaction with the goods or services provided by the store owner. Not however limited to the goods and services provided by the store owner or lessee, as any goods or services can be “advertised” using this system, so the owner/lessee can profit by having the store window as “street real estate” to be used in any way they see fit.

According to an embodiment, the user has the capability of controlling one or more of motorized displays, lights, the movement of images on a display, etc.

According to an embodiment, the system 100 is capable of sending back ordinary non-proprietary instructions to the computing device 120, so that anyone can implement the interaction as they see fit. For example, according to an embodiment, simulated keystrokes may be sent back to the computing device 120 which can be used by any program to effect visual changes.

According to an embodiment, the display screen 125 is against the window 110. According to another embodiment, the display screen 125 is projected onto the window 110. According to yet another embodiment, the display screen 125 is at a not up against the window 110 or projected on the window 110 and is at a distance from the window 110, as is shown in FIG. 1. In contrast to the existing methods of “touch screen” interaction for storefront windows, the proposed invention disassociates the area of user gesture control from the plane of the image displayed on the display 125. This provides flexibility to the designer of the interactive experience to be able to position the images or objects to be controlled anywhere in the space of the inner window area, and on any size screen on the display 125.

While the present system 100 may be installed in a number of locations, preferable locations include, but are not limited to: a streetscape, a mallscape, a museum interior, proximate to museum exhibits, incorporated into museum exhibits, dioramas, etc. Further, the present invention can enable store owners to advertise a variety of products, or advertise a cycle of individual products, giving users the ability to control the content on the display 125.

In a preferred embodiment, the present invention provides a means to offer two-way communication. In these circumstances, storefronts could also provide entertainment to passersby such as, but not limited to, interactive games, educational experiences, news feeds, location information, and other related services. Users can engage with images and other controllable physical and virtual display elements from outside the display.

According to an embodiment, the sensors 115 use structured light as the medium of sensing a user's gestures. This structured light may have a wavelength in the visible or infrared spectrum, but it may also contain light in other regions of the electromagnetic spectrum. This allows the structured light to pass through a pane of glass 110 (or other material) and be reflected back through the glass 110 to the sensor 115 with little degradation. By “structured” light, it is meant that the light is modulated to add a “signature” to it. These methods substantially improve the ability of the sensor 115 to determine that light coming back from the outside of the glass 110 is the same light that was transmitted from inside the glass 110 by the sensor 115 system, as opposed to ambient light from other sources like sunlight, exterior lights, or reflections. It is noted, however, that other types of sensors may also be used while maintaining the spirit of the present invention.

This structuring of light can be achieved by different methods. Such methods include restricting the wavelength of light to specific ranges, restricting the wavelength of light to a particular frequency, and/or pulsing the light with a given modulation pattern. In the case of wavelength restriction, for example, the source light of the sensor system may be generated as monochromatic light or dichomatic light, where this light is in a very narrow frequency band. In those embodiments, the sensor 115 is tuned to that frequency in particular, and ignores other frequencies that may enter through the window 110. This can be achieved using one or more filters or through other, not explicitly stated methods.

In alternative embodiments, the light of the present invention may be pulsed or modulated in a unique way. For example, the light could be displayed in a series of very rapid bursts or displayed in another particular pattern. Preferably, the sensor of the present invention is electronically tuned to detect incoming reflected light from outside the glass that matches the light patterns emanating from the source. This method effectively screens out stray light coming from the outside, which does not possess the signature patterns, and focuses the sensor 115 system only on its source's light emissions. Thus the source/sensor system can very accurately focus on and determine the specific actions of the nearby user 130, while also ignoring any extraneous light sources as well as light generated by reflections from nearby objects, as distinguished from reflections of the structured light source. One way in which these reflections would be distinguishable would be the strength of the reflection. That is, the reflections of the structured light would be identifiably stronger than that of the ambient light.

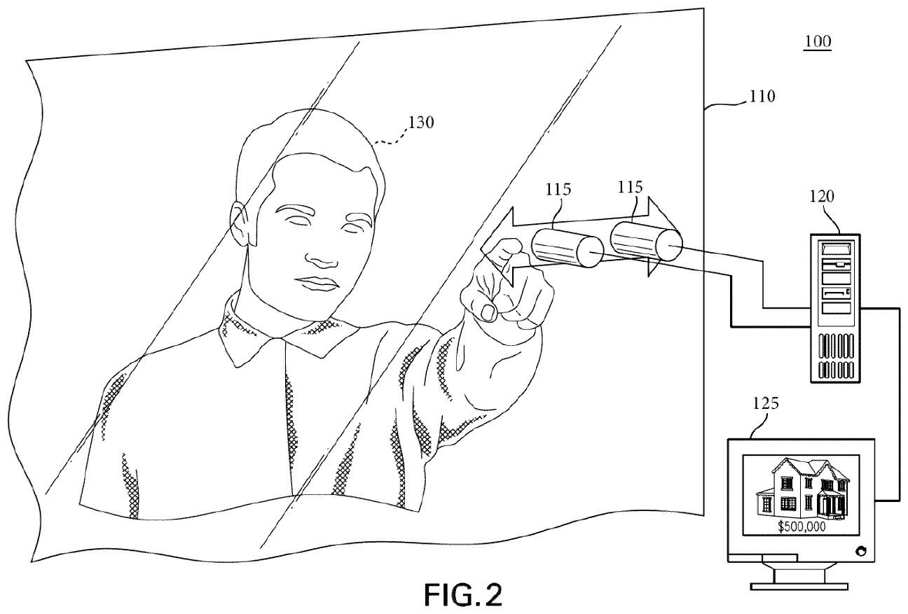

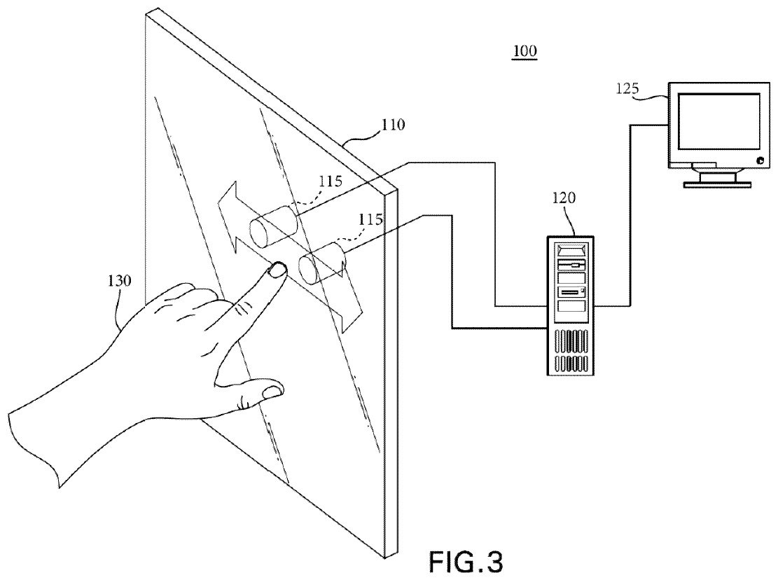

Referring now to FIGS. 2-3, a rear perspective view (FIG. 2) and a front perspective view (FIG. 3) of an interactive system 100, while in use by a human user 130, are illustratively depicted, in accordance with various embodiments.

As shown, multiple light emitters and reflection-sensing photocells 115 may be used. This embodiment is able to determine whether a user's 130 finger is near a particular area. For example, this area may correspond to standard ways of controlling a computer, as one does using a keyboard or mouse. Decals on the inside of the glass may help guide the user toward these zones. In some embodiments, five zones may be defined which correspond to left, right, up, down, and select. Decals are preferred position indicators as many types of light generated by the sensors 115 can pass through a decal uninhibited, making it possible to provide simple and direct graphical guide for the user without degrading the sensing system.

In embodiments, a standard or infrared camera 115 may be placed behind the glass 110, facing the outside of the display. The system 100 adds “structure” and “signature” characteristics to the lighting 135 (shown in FIG. 1) which emanates from inside the store window 110, such that the camera is made to focus only on the nearby user 130, and not the background imagery of other passersby, cars, or other moving objects. This greatly improves the ability of the present embodiment to focus on the most relevant aspects of the user's movements. In this embodiment, the light signal sensed by the camera can be modulated electronically using the methods described previously.

In yet another embodiment, alternatively or in addition to a user controlling images and menu choices on an external screen without touching the screen, movements of physical objects equipped with motors operatively coupled to computer 120 can be similarly controlled. In this embodiment, users may activate a variety of movements and actions of the objects using finger, hand, and/or body gestures.

In embodiments, gestures using only a single finger may allow simple interaction with a screen without touching it. Here for example, broad mouse control may be enabled and a mouse click can be signaled. The system may thus allow a user to select large menu targets, for example, in an area of 20 by 20 pixels or larger for a menu item.

To do so, the user approaches a screen which may be of any desired size, such as a 9 by 12 inch tablet or a 32 inch monitor, for example. The screen may be mounted, such as on a stand or on a wall, and its setup and appearance are preferably arranged to suggest it has “kiosk” functionality. The user controls the mouse with an index finger pointing across a field in space, perhaps 3 to 12 inches away from the screen surface, and perhaps 24 inches across by 12 to 16 inches in height, mapped to the width and height of the display. For screens larger than 24 by 16, finger movement in space more distant from the screen surface may be desirable, for example 24 inches distant for larger monitors. Moving the pointed finger in the space in front of the screen causes the cursor on the screen to track across the screen. In an embodiment, the pointing index finger may be held rigid to control movement of a virtual mouse while moving the hand. “Clicking” may then be achieved by flexing the index finger quickly, for example.

In some embodiments, the gesture-based control system is further configured to detect fine-grained finger positioning using image data processed through an AI-based hand tracking model. For example, the system may identify when a user brings the tip of the thumb and index finger together, forming a gesture similar to the commonly recognized “OK” symbol. This gesture may be interpreted as a selection input, such as a virtual mouse click or tap command.

Additionally, the system may analyze the position of the palm or the overall spatial position of the hand relative to a digital interface to identify interaction zones. As the user moves the hand through space, the system may dynamically highlight interactive regions within a user interface. For instance, in a wayfinding application on a digital map, such as a building directory or shopping mall display, the user may hover the hand over a designated region, causing the system to highlight a specific store or office. If the user performs a tap gesture e.g., by bringing the thumb and forefinger together while that region is highlighted, the system may interpret the input as a “pick” command and present additional location-specific information. A subsequent left-to-right waving gesture may be interpreted as a dismissal command, reverting the interface to a previous state or higher-level map view. The AI-based gesture recognition engine may utilize pose estimation and skeletal tracking to accurately resolve individual fingers and joints, enabling high-precision detection of hand movement and finger articulation. The system may be implemented to reliably differentiate between intentional selection gestures and natural hand movements, thereby supporting intuitive and touchless interaction across a range of applications.

This embodiment can be arranged to work with a variety of monitors or tablets, for example by mounting one or more sensors and detectors to a frame, and using a clamp to attach the frame to the device having the screen. Such an arrangement may be configured using a USB port or Bluetooth pairing, for example. Plug and play recognition of the embodiment as a mouse may also be implemented. Advantageously, such an arrangement can work through glass, as in a store window display, but this is not a requirement.

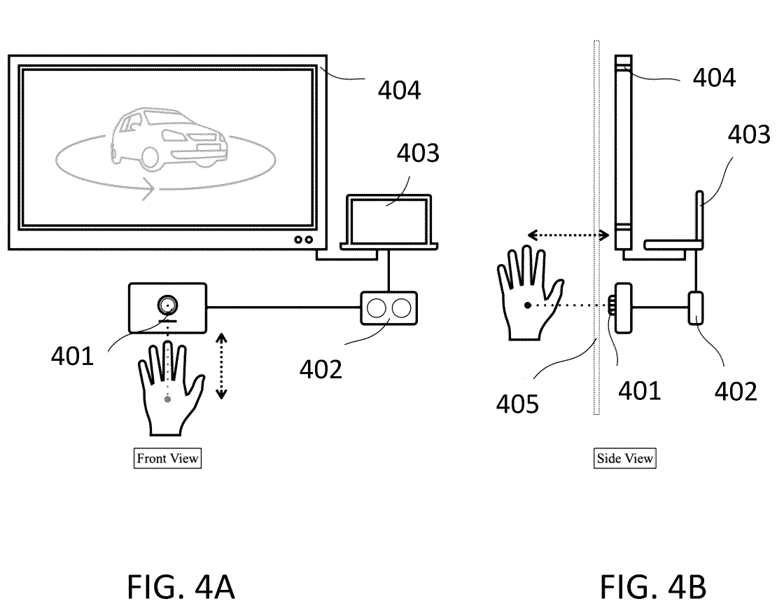

Turning now to FIGS. 4A and 4B, illustrated are front and side views, respectively, of an embodiment that comprises a distance ranging infrared sensor 401, an interface board 402 to track the sensor output and send tracking information to a computer, the computer 403, and a display 404. The distance ranging sensor 401 is capable of operating through single or multiple glass panes of a window 405 as are commonly found in a store front, or simply in the air. This embodiment provides “no touch” control of a dynamic image on the computer screen 404 simply by moving a hand closer or farther from the sensor to produce dynamic distance information. The dynamic distance information can be used in many ways, one of which is to control the rotation of an object displayed in on the screen in a 3D rendering. In a usage example, a user may use their hand to rotate a 3D image of a necklace displayed in a jewelry store window to see it from different angles. In another usage example, outside a car showroom a user may control a 3D view of a car to view it from many angles, as shown in the figure.

In some embodiments, it is further contemplated that artificial intelligence (AI)-based tracking capabilities may enhance or replace traditional distance-ranging techniques. Advances in AI model accuracy and/or real-time inference have improved the practicality and reliability of such implementations. For example, AI-driven 3D hand tracking may be used to detect the rotation of the user's hand in space, enabling intuitive control over the orientation of displayed objects. The rotation of a user's hand may be mapped to the rotational control of a product rendering, such as a vehicle or piece of jewelry, providing a seamless and natural interface for visual exploration. Additionally, this rotational tracking may be extended to control scrolling through a series of interface elements, such as menu items and/or product selections, thereby expanding on the previously disclosed “swipe left/right” gesture modality using familiar and low-effort hand motions, all without requiring physical contact with a surface or sensor.

In some embodiments, the gesture-based control system is designed with an emphasis on simplicity and user intuitiveness, eliminating the need for users to learn, memorize, and/or repeatedly practice complex signaling systems or predefined gesture vocabularies. Instead, the system leverages familiar, naturally occurring hand movements that are already part of most physical and cultural repertoires of a user. These may include but are not limited to one or more universally recognized gestures such as a “swipe” motion to indicate navigation, a “thumbs up” to confirm or approve an action, a “thumbs down” to reject or dismiss a selection, and/or the “OK” symbol, formed by touching the thumb and index finger, which may be interpreted as a selection or confirmation input. By recognizing and interpreting these common, intuitive gestures using AI-based hand and finger tracking, the system lowers the cognitive and physical effort required for effective interaction. Users are not burdened with learning complex sign language, for example, such as gestures and/or navigating a steep learning curve. This design approach enhances accessibility and user engagement across a broad range of demographics, including users with limited technical experience or physical impairments, and supports rapid adoption in both consumer and commercial environments.

Notably, the “no touch” aspect of this system is advantageous in situations where users are reluctant to touch a glass surface or a touch screen in a public installation because of known or perceived exposure of those surfaces to contaminants.

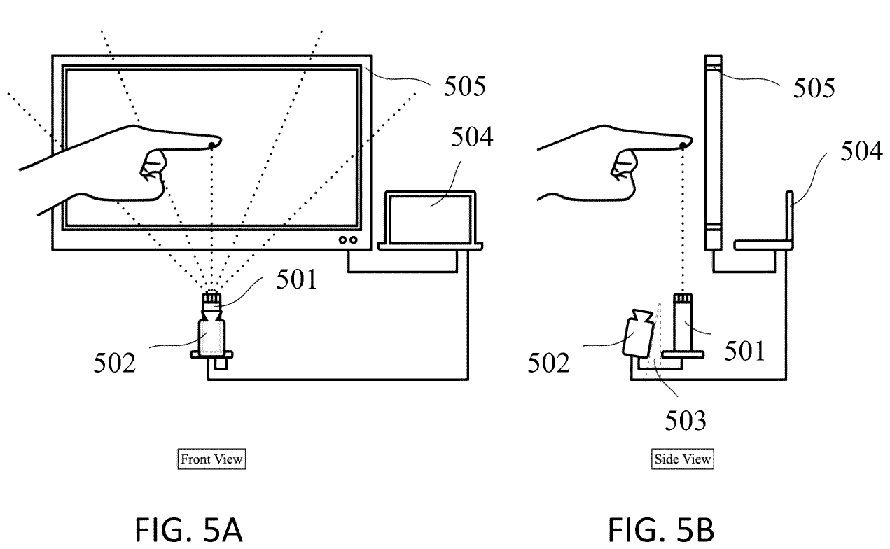

As illustrated in FIGS. 5A and 5B, front and side views, respectively, of another exemplary embodiment is also functional through a pane of glass or directly, for example near a computer screen in a typical “kiosk” arrangement that includes the computer screen mounted on a stand or a wall, or disposed on a desk in a public location. Light from at least one laser 501 is arranged to define a plane of laser light parallel to the screen 505, or a pane of glass of a storefront. This may be done for example by splitting the laser light into many lines, or by sweeping the laser through an angle at a high frequency, where the location of the laser light source (which may be one or more mirrors reflecting light from the laser) and the sweep angle are sufficient to define a plane that a user's finger can penetrate and move in. A select area of the light plane may cover or be mapped to the whole screen, or a relevant part of the screen. Preferably, the laser light is directed away from the user and other people, so it doesn't shine into anyone's eyes. The system is preferably arranged to define the plane of laser light at a distance of 1 to 5 inches from the glass or screen, although this specific distance range is not a requirement. Thereby, this arrangement displays a prominent monochromatic laser spot onto a user's finger when the finger crosses the plane defined by the laser light. The light spot can be easily distinguished from a dynamic field of view in a public location to enable accurate tracking of the finger. At least one camera 502 may be mounted to face toward an edge of the plane in a vertical direction at a small angle 503 to the plane of laser light. Another camera may be mounted to face toward an edge of the plane at a small angle in a horizontal direction (not shown), to provide at least two vantage points from which the position of the dot on the user's finger can be triangulated by the computer 504. Alternatively, one or more mirrors may be used to reflect image(s) of the dot to the camera, so there are at least two vantage points from which the position of the dot can be triangulated by the computer 504. The position of the dot is used by the computer to cause the screen 505 to manipulate an image displayed on the screen. The laser and camera may also be disposed inside a glass storefront window facing toward the glass at a small angle almost parallel to the glass surface. The laser light may be refracted outward through the window glass, and the image seen by the camera may be refracted inward through the window glass in a similar fashion, so that neither the laser nor the camera are disposed outside the glass.

The tracking of the laser dot on the illuminated finger is done by triangulating the position of the dot from images provided by the cameras, which provide image data continually or periodically at a high frequency, such as 100 Hz, that is sent to the computer. A program running on the computer uses the image data to triangulate the position and motion of the dot and generate x and y coordinates of the dot on the finger relative to the screen or glass. The computer may use the generated coordinates to cause a cursor image to be displayed on the screen or glass, so the user has an interactive sense of controlling the cursor using a virtual mouse. A “click” of the virtual mouse may be realized by the user rapidly moving the fingertip, causing a corresponding rapid movement of the dot on the finger, resulting in rapidly changing dot position data that can be interpreted by the computer as a clicking motion. Alternatively, a second plane of laser light may be generated in a manner similar to the first plane, parallel to and near the first plane, so that the rapid motion of the finger causes the fingertip to briefly cross the second plane to cause a second dot to appear on the finger, which can be interpreted by the computer as a clicking motion.

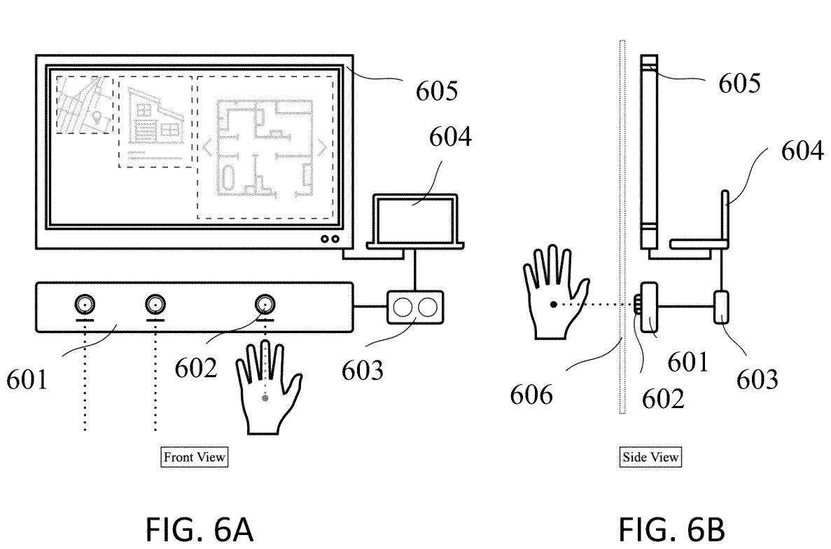

Another embodiment, illustrated in FIGS. 6A and 6B, uses data from multiple sensors to control structured menus. This implementation uses a plurality of sensors 602, one for each menu level and preferably at least three, mounted in a sensor block 601 to control “nested menus” displayed on the screen or glass, thereby enabling the user to navigate through choices associated with a controlled entity, for example by displaying images and/or information of items stored in a database. Illustratively, the user can “page or scroll” through choices in a top level menu (shown on the left side of screen 605), such as by waving or making an appropriate predetermined gesture in front of a top level sensor (the sensor toward the left side of sensor block 601). The gesture and its position may be identified by cameras 603, and conveyed to computer 604, which controls what is displayed on screen 605. For example, making appropriate gestures in front of the top level sensor may display a list of top level choices on the screen, and allow the user to scroll through the choices and select a desired one. The user can then make appropriate gestures in front of the second level sensor (the sensor nearest the center of sensor block 601) to display a list of second level choices, scroll through the choices, and make a second level selection. Likewise, the user can then make appropriate gestures in front of the third level sensor (the sensor nearest the right side of sensor block 601), to display a list of third level choices, scroll through the list, and make a third level selection. Thus, each menu level selection causes further information of the selection to be displayed in another menu “below” it in the menuing hierarchy. A simple example would be in a real estate office window display, where the top level menu choices may correspond to neighborhoods covered by the office, the second level menu may show property listings in the chosen neighborhood, and the third level menu may show pictures and information of a particular selected property. Thereby, it is easy to use nested menus to access information of an arbitrarily large number of properties, including data and images of each property stored in a database.

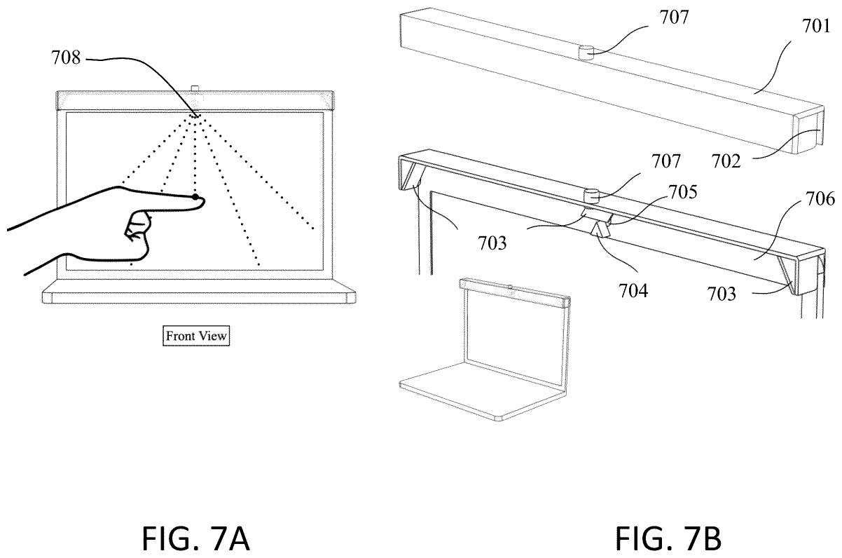

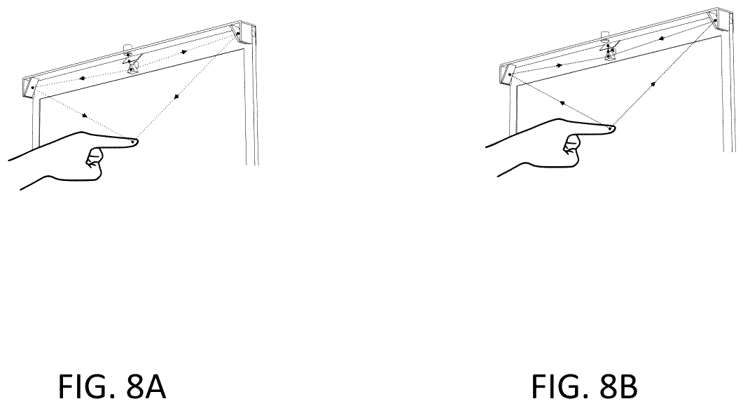

Another exemplary embodiment includes the use of optical add-on devices for use with a laptop having a webcam for finger tracking. Two arrangements will be described, with and without a laser. As illustrated in FIGS. 7A and 7B, in a first implementation (without a laser), a clip-on optical device is coupled to the top of a typical laptop screen 706 when the laptop is open. The device may include a body 701 that holds the other elements in place. A clamp 702 is used to removably couple the device to the top of the laptop screen, and an adjustment knob 707 may be provided to adjust the placement of the device on the laptop screen. A plurality of mirrors 703 reflect light into the webcam 705 of the laptop to gather information about the location of a finger hovering over the screen at a distance, preferably 1 to 3 inches from the screen, although other distances may be used. One of the mirrors 703 is disposed in front of the webcam 705 to deflect the view of the webcam downward. A beamsplitter 704 bisects the camera view left and right, and two mirrors 703 disposed at the corners of the upper part of the laptop screen deflect the view downward and toward the center of the screen from the top left and top right corners. Thus using the existing webcam of a laptop, two images of a finger pointed at the screen are provided to the webcam from two different vantage points (i.e., from the locations of the mirrors in the corners). From the images, a position of the finger can be triangulated and x and y coordinates relative to a select or default corner of the screen can be calculated by the laptop. The user's finger can also be tracked as it moves in front of the laptop screen, and the laptop can determine what elements displayed on the screen the finger is pointing to. A distance of the fingertip from the screen can also be determined, which can be used to interpret a “select” gesture. FIG. 8A illustrates how the webcam has two lines of sight that allow it to cover essentially the entire laptop screen, including the location of the finger, from the two corner vantage points. FIG. 8B illustrates how the finger, illuminated by ambient light or light from the screen for example, can cause light impinging on the finger to be reflected back to the camera along two optical paths, from which the x and y coordinates of the position of the fingertip can be calculated.

Alternatively or additionally, a laser 708 may be introduced into the system, also pointing downward from the frame. The laser light may be either split into a plurality of beams or be made to sweep rapidly back and forth through an angle to define a plane parallel to the screen. The laser will cause a prominent dot to appear on the finger when the finger pierces the plane. All other aspects of the system remain the same. The dot may enable the laptop to more quickly and accurately calculate the coordinates of the finger and track its movements than can be achieved using just ambient or screen generated light.

Thus, the present invention improves upon the prior art by only placing its sensing devices against the glass 110 (or other transparent material), for example as a storefront window, which then communicate with a screen 125 which can be located anywhere inside the storefront. This greatly enhances the visibility of the screen 125, and affords a designer greater flexibility in designing the window display, due in part to the ability to place the screen 125 at any location. Further, the present invention uses different methods of applying a “signature” to the light source, so that it is not restricted to infrared frequencies. Additionally, the present invention alternatively uses a camera to determine the shape and position of a user's appendage (e.g., a finger) and track its movements. Further, the present invention does not require that the user touch the glass or other tracking surface, which is a large departure from the prior art which generally requires the user to touch the tracking surface.

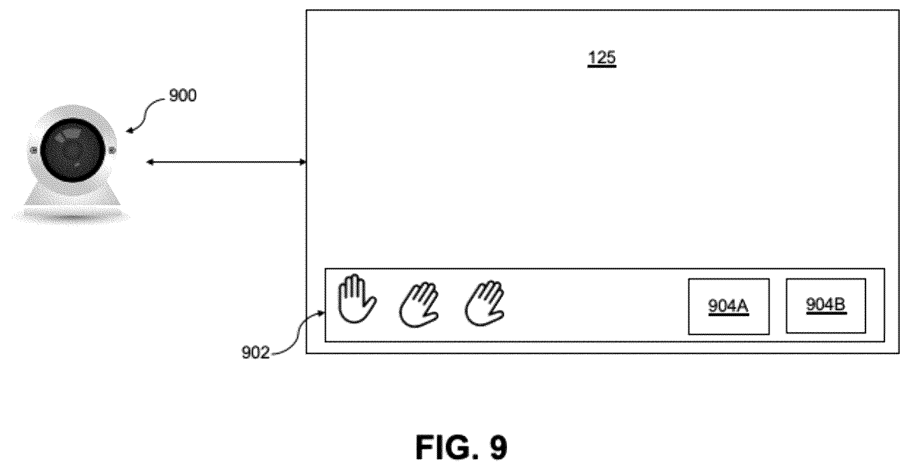

In an alternative implementation, and as shown in FIG. 9, a web cam 900 or a camera (not shown) is used to deliver real-time visual feedback of a hand of the user 130. A partial video feed strip 902 is displayed in real-time on a location of the display screen 125, such as a bottom location as shown in FIG. 9, so that the user 130 can see the position and motion of their own hand as it's waved in the air to control the display content. One or more target boxes 904A, 904B are displayed in the partial video feed strip 902, delineating one or more “menu” items that the user 130 can control. It should be appreciated that a quantity of the one or more target boxes 904A, 904B is not limited to any particular quantity. This enables a hierarchical menuing system that can allow choices from a wide variety of images, videos, or even other content, like the playing of songs. The video targets, which display real-time movements of the hands of the user 130, create a simple, natural and clear feedback loop for the user 130 to control the content. As an illustrative example, the one or more target boxes 904A, 904B can be labeled on the display screen 125 with categories and choices, such as “real estate listing”, “pictures of the house listed”, “price ranges”, etc. in the typical usage in a real estate office.

While the real-time position of the hands of the user 130 is continually displayed as a guide to executing menu choices, at the same time, the computer 604 or a microcontroller controlling the content is tracking the state of the pixels in the tracking zones, to detect movement, and thus to execute commands to display the content associated with the menu controls of the targets. For example, one target labeled “listings” in the real estate example might “page” through many listings currently for sale. The choice of detailed photographs of the exterior and interior or other details of the individual listing could be shown when the user 130 waves a hand over a second target area labeled “images of this listing”. The content can be linked hierarchically or summoned in real-time from a database query.

In a further elaboration of the “gestures” of the user 130, control logic tracking the pixels can easily be made to analyze movement within the target video area, as in the commonly used gesture “swipe right” or “swipe left”. This allows for even more degrees of control of the content, since the pixels tracked in each target area can be scanned to detect motion across the target zone, either in a “left to right” direction. This can be expanded to track for an “in and out” direction, since the tracked pixels, which are detected when the hand is closer to the camera or the web cam 900, would be a larger area than when the hand of the user 130 is farther away, and seen as “smaller” by the camera or the web cam 900, taking up fewer pixels in the scanned target area. These modalities of tracking enable a more “analog” set of values which could, for example, execute the rotation of an image in the display screen 125, for example letting the user 130 see an image of a car as it spins in three-dimensions.

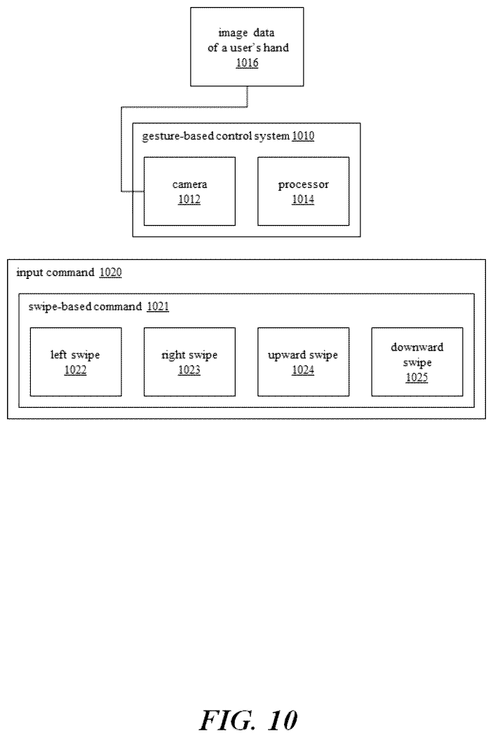

FIGS. 10-14D illustrate example embodiments of gesture-based control systems and methods implementing artificial intelligence (AI) for user input detection and interface control. In certain embodiments, the system includes one or more sensors configured to detect user hand movements within a defined spatial region, wherein said movements are interpreted as input commands. The sensor array may include infrared (IR) sensors or equivalent proximity-based detection technologies capable of identifying the presence and motion vectors of a user's hand relative to a defined sensing zone. In alternative embodiments, the system comprises a camera-based input module operable to provide visual feedback to the user, wherein hand position and motion are rendered in relation to graphical user interface elements or predefined video targets.

In further embodiments, the system employs AI-enabled gesture recognition techniques to interpret hand movements directly from real-time image data captured by a camera. This implementation eliminates the need for physical proximity to hardware sensors and does not require visual feedback, thereby allowing for greater flexibility in user hand positioning within the field of view of the camera. The AI module utilizes machine learning models trained on a library of gesture image data to detect and classify gestures, which are then mapped to corresponding control commands within the digital interface. For example, machine learning techniques are employed to detect and classify hand gestures using real-time camera input. The system matches live video images of the user's hand to a library of stored hand image models representing a wide range of hand types, positions, and gesture contexts. As a result, the system can accurately recognize the hand's position, orientation, and even handedness (i.e., distinguishing between right and left hands), as well as finer details such as finger positioning, including whether the thumb and forefinger are touching or whether a “thumbs up” or “thumbs down” gesture is being made.

The interface paradigm remains intentionally simple to maintain an extremely low learning curve: the basic instructional prompt is merely “swipe your hand.” There are no complex or memorized gesture sets required. The swipe gesture is nearly universal, widely adopted in touchscreen devices and culturally reinforced by media portrayals such as in the film Minority Report. The action of swiping, left, right, up, or down, has become an intuitive and familiar interaction modality, requiring minimal user training. This simplicity is further reinforced by the system's focus on binary motion gestures rather than intricate or nuanced hand signs such as those used in sign language. For example, a left-hand swipe may be interpreted as a backward command, while a right-hand swipe may represent a forward command. Swipes upward or downward may represent menu navigation across hierarchical options. Additionally, the system can implement universally understood static gestures like holding up a palm to represent a “stop” or “restart” command.

Building on the “menuing” system, this AI-driven implementation allows a user to navigate deep content hierarchies with ease. By designating two or three screen “targets” that represent major content categories, a user can perform swipe gestures to access subcategories or content details, enabling control of potentially hundreds of content items through a streamlined, gesture-based navigation structure to introduce spatial flexibility. The AI system allows user hands to be located anywhere within the field of view of a camera rather than other systems where gesture detection is constrained to a defined physical space in front of a sensor or video feed. The space between the user and the screen is virtually divided into regions corresponding to the left or right hand, but actual recognition is based on identifying hand type and movement rather than strict spatial positioning.

To aid usability, the system may optionally include a real-time video overlay or “shadow” projection of detected hand gestures, providing the user with intuitive visual cues. In alternate embodiments, the overlay may be omitted entirely, with gesture inputs still recognized in the background, allowing a fully immersive experience without screen clutter. This system is particularly well-suited for use in environments where visual attention is limited or where physical contact with a control interface is impractical or unsafe. Example use cases include: touchless control of industrial machinery; hands-free navigation of media interfaces while driving; interaction with smart home devices while seated or away from a touch panel; activation of utilities like faucets or lights; and virtual environment control during immersive VR or AR headset use. Further, demonstration systems implemented on standard laptops with built-in cameras confirm the system's functionality. For instance, a user may swipe a hand upward or downward to toggle between high-level options, or swipe left or right to navigate content tracks or adjust settings. Both modes, with or without a hand shadow indicator, are supported, depending on user preference and application context.

As noted above, in certain embodiments, the gesture-based control system may be applied to enable hands-free navigation of media interfaces while driving. To maintain driver safety and minimize distraction, the system is configured to recognize and/or respond to single-handed gestures that may be performed with minimal deviation from normal driving posture. For example, a driver may briefly perform a left or right swipe gesture with one hand, while the other remains on the steering wheel, to change audio tracks or switch between media sources. Likewise, a thumbs-up or thumbs-down gesture may be used to indicate content approval or dismissal, respectively. The system's camera may be positioned to monitor an accessible region, such as just above the steering column or to the side of the dashboard, thereby ensuring reliable gesture capture without requiring the driver to fully remove their hand from the wheel and/or divert their attention from the road.

While recent advancements in artificial intelligence (AI), including the use of machine learning models and large language models (LLMs), have enabled some systems to interpret human movement, many of these approaches are optimized for complex gesture vocabularies, motion prediction, or multimodal input integration. Such systems often require extensive training datasets, structured user inputs, or controlled environments to achieve reliable performance. In contrast, the present disclosure relates to a gesture-based control system configured for simplicity, immediacy, and universality, emphasizing natural, low-effort gestures that are already familiar to users (e.g., swiping or a thumbs-up). Rather than attempting to decode nuanced or symbolic gestures or track full-body movements, the system focuses on recognizing a minimal set of intuitive hand motions using efficient computer vision and lightweight machine learning models. This approach allows real-time interaction without the complexity or user burden typically associated with more generalized AI-driven movement interpretation platforms.

FIG. 10 illustrates a gesture-based control system 1000 is configured to interpret hand gestures as input commands for controlling a digital interface. The gesture-based control system 1000 includes a camera 1012, which is configured to capture image data 1016 representing a user's hand in real-time. The camera 1012 may be integrated into or operatively connected to a computing device such as a laptop, tablet, smartphone, smart display, or other computing terminal. The system 1000 further includes a processor 1014 operatively coupled to the camera 1012. The processor 1014 is configured to execute one or more machine learning models to process the image data 1016 and detect hand gestures by comparing the captured data with a set of pre-stored hand image models. These models may include hand images in a variety of poses, lighting conditions, and orientations. Upon detecting a gesture, the processor 1014 is configured to determine one or more gesture attributes, including but not limited to hand position, handedness (e.g., left or right hand), motion vector, and orientation.

Once a gesture is identified, the processor 1014 maps the recognized gesture to a corresponding input command 1020. As shown in FIG. 10, the input command 1020 may include a swipe-based command 1021, which comprises directional inputs such as a left swipe 1022, right swipe 1023, upward swipe 1024, and downward swipe 1025. These gestures may be mapped to corresponding actions within a digital user interface, including content navigation, option selection, and system control functions. In some embodiments, the processor 1014 is further configured to detect static gestures such as a “thumbs up,” “thumbs down,” or “stop” gesture, and associate each with a respective system command. Additionally, the processor 1014 may determine whether a thumb and forefinger are in contact, enabling recognition of pinch or similar gestures.

In some embodiments, the content displayed on the display of an electronic device and navigated via user gestures may include live and/or dynamically updated data retrieved from one or more external data sources, rather than static and/or preloaded content. For example, the system may be configured to query and display real-time property listing data from a network-connected source such as the Multiple Listing Service (MLS) or a similar real estate database. The MLS is a structured data repository containing extensive property-related information, including pricing, availability, square footage, location, images, agent contact details, and open house schedules. The gesture-based interface enables users to interactively explore and filter such listings by performing intuitive hand gestures, for instance, swiping to scroll through property cards, performing a “pinch” gesture to zoom into map-based listings, and/or tapping (e.g., thumb-to-forefinger gesture) to select and drill down into property details. Because the underlying database may be continuously synchronized in real-time, in some examples, the information presented to the user mat reflect current and/or accurate market data, including recent updates to listing status, price changes, and/or new availability. In some embodiments, a dynamic connection provides users, via the system, with up-to-date, query-responsive content, rather than relying on static and/or periodically refreshed data. In some embodiments, the system may also support gesture-based search refinement, allowing users to intuitively filter live data results by category (e.g., price range, location, or property type) using directional and/or symbolic gestures, thereby enhancing the relevance and immediacy of the interaction.

The gesture-based control system 1000 may further include a navigation module configured to traverse hierarchical content structures based on swipe direction and gesture input. In some implementations, the system 1000 may optionally include a visual feedback feature, such as a display overlay of a hand “shadow” or gesture outline, to assist the user in aligning gestures with the interface. Alternatively, the system may function in a feedback-free mode in which gesture recognition occurs in the background without displaying gesture indicators. The system 1000 is configured for low-latency operation, optionally achieving response times of less than 200 milliseconds between gesture input and command execution. The camera 1012 and processor 1014 may support recognition of multiple hands simultaneously, and the gesture models may be dynamically updated in response to environmental changes or newly collected training data.

In addition, the system 1000 may include environmental adaptation functionality, such as real-time contrast adjustment or edge enhancement, to improve gesture detection under variable lighting and background conditions. Audio tones or haptic feedback mechanisms may be used to confirm gesture recognition events. Accordingly, the system 1000 enables touchless, intuitive interaction with digital systems using naturally performed hand gestures and supports a wide range of applications requiring minimal training or hardware constraints.

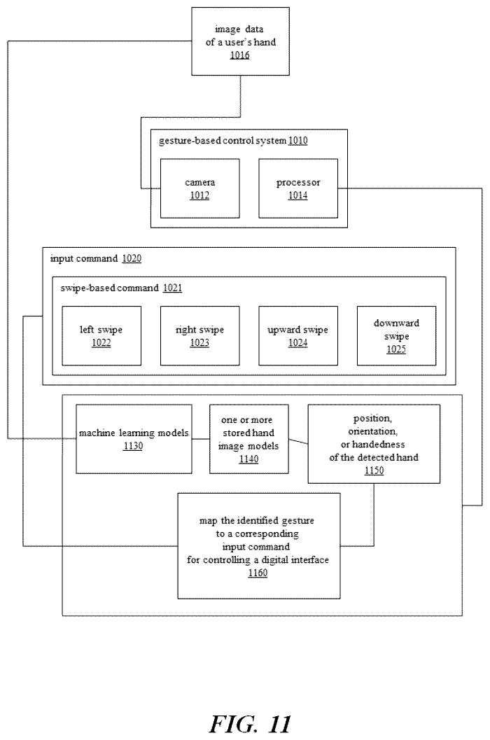

FIG. 11 illustrates a block diagram of the gesture-based control system 1010. This figure expands upon the architecture introduced in FIG. 10, highlighting internal modules and data flow associated with gesture recognition and input command generation. The gesture-based control system 1010 receives image data 1016 representing a user's hand via a camera 1012. The image data 1016 is transmitted to a processor 1014, which is configured to perform gesture classification and command generation. The processor 1014 accesses a set of machine learning models 1130, which are trained to detect and classify hand gestures based on comparisons with one or more stored hand image models 1140. These stored image models represent a wide range of hand postures, orientations, and lighting conditions. By applying the machine learning models 1130 to the incoming image data 1016, the system identifies a user's hand and classifies the gesture being performed.

The system further analyzes gesture attributes, including position, orientation, or handedness of the detected hand 1150, to refine the classification result. For example, the processor 1014 may distinguish between gestures made with the left or right hand, determine whether the hand is tilted, or recognize directional movement across the frame. Once a gesture is identified and its characteristics are evaluated, the system maps the identified gesture to a corresponding input command 1160 for controlling a digital interface. As described in the claim structure, the input command may comprise a swipe-based command 1021, including a left swipe 1022, right swipe 1023, upward swipe 1024, or downward swipe 1025. These commands can be used to navigate, select, or manipulate interface elements in real-time. The digital interface controlled by the gesture-based system may be implemented across various devices and applications, such as smart displays, augmented or virtual reality environments, automotive infotainment systems, industrial machinery, or smart home interfaces.

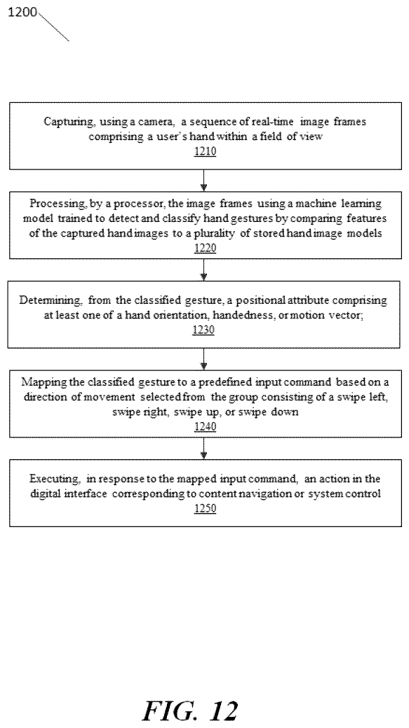

FIG. 12 illustrates a flowchart describing a computer-implemented method 1200 for gesture-based control of a digital interface. The method begins at block 1210, where a camera captures a sequence of real-time image frames comprising a user's hand within a field of view. The image data is then passed to a processor, which performs subsequent analysis blocks. At block 1220, the processor processes the captured image frames using a machine learning model trained to detect and classify hand gestures. This is performed by comparing features extracted from the live hand imagery with a plurality of stored hand image models, which represent different hand positions, orientations, and configurations under varying conditions.

At block 1230, the processor determines, from the classified gesture, one or more positional attributes, which may include the orientation of the hand, whether the gesture was performed with the left or right hand (i.e., handedness), or the directional motion vector of the hand. In block 1240, the classified gesture is mapped to a predefined input command based on the detected direction of hand movement. The recognized movement direction may be selected from the group consisting of a swipe left, swipe right, swipe up, or swipe down. Each direction corresponds to a unique system control action or interface navigation operation. At block 1250, the system executes an action in the digital interface based on the mapped input command. The action may include content navigation, item selection, scrolling, or other system control functions within the digital environment. This gesture-based interaction enables a touchless and intuitive user interface experience.

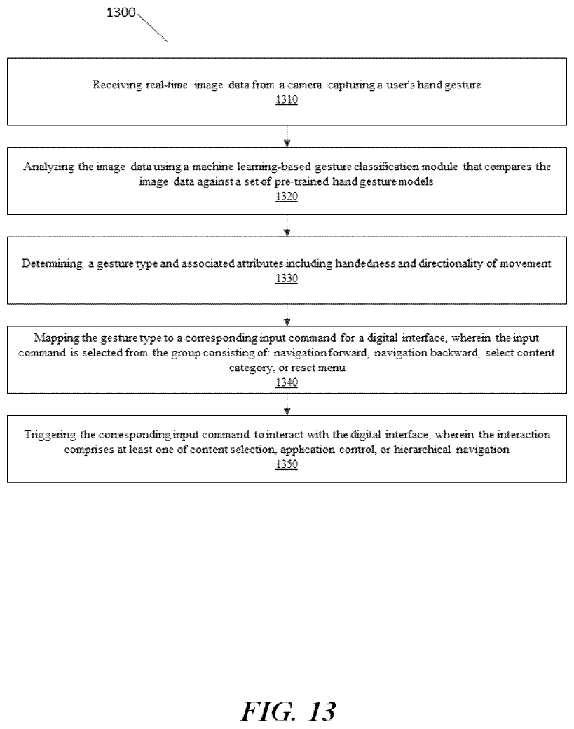

FIG. 13 illustrates a flowchart of a method 1300 which is executed by a computing system via a non-transitory computer-readable medium storing instructions. When executed by one or more processors, these instructions cause the system to perform a gesture-based control method for interacting with a digital interface. At block 1310, the system receives real-time image data from a camera configured to capture a user's hand gesture. The captured data comprises one or more video frames in which the user's hand appears within the field of view of the camera. At block 1320, the system analyzes the image data using a machine learning-based gesture classification module. This module processes features of the incoming hand images by comparing them against a set of pre-trained hand gesture models. The models may encompass a wide range of hand shapes, sizes, orientations, and lighting conditions. At block 1330, the system determines a gesture type from the classified result, along with associated gesture attributes. These may include handedness (e.g., left vs. right hand), the directionality of movement, and other spatial characteristics of the gesture.

In some embodiments, the processor is further configured to detect the presence of multiple hands and process each hand's gesture independently and/or concurrently, enabling multi-user or multi-hand input scenarios. This allows for interaction models, such as distinguishing between dominant and/or non-dominant hand commands and/or supporting collaborative control in shared environments. Additionally, while the system utilizes a pre-trained gesture recognition model, for example, based on a large language model (LLM) or vision transformer trained on a broad set of hand gesture datasets, it is also capable of adaptive tuning to improve gesture recognition accuracy in real time. During an introductory user experience, the system may prompt the user to engage in an onboarding sequence to calibrate gesture detection under localized conditions, such as ambient lighting, hand shape, skin tone, and/or movement style. For example, upon system initialization, a display may prompt: “Welcome to FutureMall. Would you like to navigate using gestures? If so, please give us the OK sign.” Once the user performs the designated gesture (e.g., thumb and forefinger touching), the system begins mapping user-specific gesture features to the stored model.

This user-aware tuning process allows the processor to dynamically refine the gesture recognition model based on environmental feedback and individualized input characteristics, thereby improving precision and reducing false positives or misclassification. The adaptive model may continuously update as new data is captured, allowing the system to evolve over time to reflect the user's preferred gestural style and context of use. This approach improves robustness in diverse settings and supports deployment in real-world environments where gesture variability and ambient conditions cannot be tightly controlled.

At block 1340, the gesture type is mapped to a corresponding input command for a digital interface. The input command may be selected from a predefined set that includes, but is not limited to: navigation forward, navigation backward, select content category, or reset menu. This mapping enables the user to interact with interface elements through intuitive, directional gestures. At block 1350, the system triggers the corresponding input command to perform one or more control actions in the digital interface. These actions may include content selection, application control, or hierarchical navigation, depending on the context of use. The method of enables hands-free, gesture-based interaction with computing systems, improving accessibility, user experience, and control flexibility across a range of applications, including smart displays, virtual interfaces, automotive controls, and consumer electronics.

Conventional user interfaces often require physical interaction through mechanical peripherals such as keyboards, touchscreens, or remote controls. These systems pose usability limitations in environments where hands-free interaction is desired or necessary, for example, in sterile settings, while operating machinery, when using wearable or immersive displays, or for users with physical limitations. Additionally, gesture recognition systems in the prior art typically require structured environments with fixed sensing zones, specialized infrared hardware, or rigid gesture libraries that involve steep learning curves and limited adaptability.

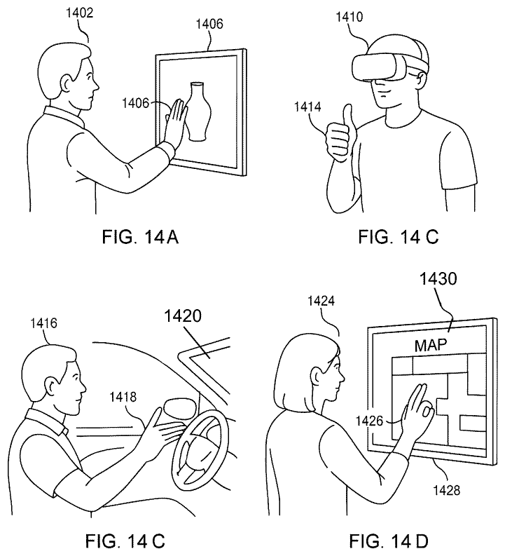

FIG. 14A illustrates a front-elevation view of an example embodiment in which a user 1402 interacts with a digital interface controlled by the gesture-based system. The user stands before a storefront smart display 1406, with one or more sensors including, but not limited to, an overhead camera. The system captures a single-hand swipe 1406 along a trajectory, which is interpreted by the processor as a rotational input command. This command is applied to a three-dimensional product rendering, such as any image such as, a necklace or vase, displayed on the smart display 1406. The user can rotate the object by gesture alone, allowing for contactless, immersive product viewing through a window or glass panel, all mediated through the digital interface controlled by the gesture-based system.

FIG. 14B shows a perspective view of a virtual reality (VR) user wearing a headset 1410 and interacting with a digital interface controlled by the gesture-based system. The user performs a thumbs-up gesture 1414, detected by inward-facing cameras integrated into the headset. The processor interprets the gesture as an affirmative input, such as confirming a menu selection or progressing through content. The gesture-based system maps the recognized gesture to a corresponding command within the immersive interface, enabling seamless interaction without physical controls.

FIG. 14C depicts a partial interior view of a vehicle where a driver 1416 interacts with a digital interface controlled by the gesture-based system embedded in the vehicle's infotainment display 1420. A dashboard or headliner-mounted camera, for example, captures a one-handed swipe gesture 1418, which is processed as a forward-navigation command. This allows the driver to scroll through media, navigate menus, or adjust display content, all through intuitive, single-hand input. Importantly, the driver maintains one hand on the steering wheel, demonstrating the system's suitability for safe, low-distraction operation in automotive environments fully facilitated by the digital interface controlled by the gesture-based system.

FIG. 14D presents a front-elevation view of a public kiosk application. A shopper 1424 uses an “OK” gesture 1426 in front of a mall directory 1428, which is part of a digital interface 1430 controlled by the gesture-based system. When the gesture is detected over a highlighted store icon, the system retrieves and displays additional store information. A follow-up gesture, such as a swipe or thumbs-down, may dismiss the content, enabling the user to navigate back through the directory interface. This illustrates how the gesture-based system enables fluid, multi-level content exploration in public-facing, touch-free installations.

A cross FIGS. 14A-14D, the digital interface controlled by the gesture-based system is implemented across a diverse range of hardware platforms and application contexts, including smart displays, immersive VR environments, vehicle infotainment systems, and interactive public kiosks. The system interprets simple, culturally intuitive gestures—such as swiping, thumbs-up, and the “OK” sign—without requiring the user to memorize complex gesture vocabularies or follow structured training. This results in a highly accessible, low-friction human-machine interface that enables real-time, contactless control in both commercial and consumer settings.

FIGS. 10-14D illustrate a technical solution to these challenges through a gesture-based control system that leverages real-time image acquisition, machine learning-based gesture recognition, and dynamic command mapping to enable intuitive and contactless interaction with digital interfaces. The technical solution centers on a system architecture (FIGS. 10 and 11) and computer-implemented methods (FIGS. 12 and 13) that employ a camera 1012 to capture real-time image data 1016 of a user's hand. A processor 1014 executes machine learning models 1130 trained on a diverse set of stored hand image models 1140 to detect and classify gestures without requiring specialized sensors or predefined gesture zones. The system further extracts positional attributes 1150, such as orientation, handedness, and motion direction, allowing for robust interpretation of both static and dynamic gestures across varied environments and lighting conditions.

Classified gestures are mapped to predefined input commands 1020, such as swipe left, swipe right, swipe up, or swipe down (FIG. 10), or to functional interface operations such as navigation, selection, or resetting a menu (FIGS. 12-13). The architecture supports both feedback-enabled and feedback-free modes, offering visual overlays or fully immersive interaction depending on user preference or application context. This solution improves the accuracy, flexibility, and accessibility of gesture-based interfaces, reducing hardware complexity and enabling real-time control across a wide range of computing platforms, including but not limited to, mobile devices, smart displays, automotive interfaces, virtual reality systems, and assistive technologies.

### EXAMPLES

Clause 1. A gesture-based control system comprising: a camera configured to capture real-time image data of a user's hand; a processor operatively coupled to the camera, the processor configured to: apply one or more machine learning models to the image data to detect a hand and identify one or more gestures based on a comparison with one or more stored hand image models; determine a position, orientation, or handedness of the detected hand within a field of view of the camera; and map the identified gesture to a corresponding input command for controlling a digital interface; wherein the input command comprises a swipe-based command selected from the group consisting of a left swipe, a right swipe, an upward swipe, or a downward swipe.
Clause 2. The system of clause 1, wherein the processor is further configured to distinguish between a left-hand gesture and a right-hand gesture to generate differentiated input commands.
Clause 3. The system of clause 1, wherein the plurality of stored hand image models includes hand images in multiple orientations, lighting conditions, and backgrounds.
Clause 4. The system of clause 1, wherein the camera is integrated into a laptop, tablet, smart display, a microcontroller-based system, or mobile device.
Clause 5. The system of clause 1, wherein the gesture is identified as a static gesture selected from the group consisting of a “thumbs up,” “thumbs down,” or a “stop” gesture.
Clause 6. The system of clause 1, wherein the processor is further configured to determine whether a thumb and forefinger are touching in the image data.
Clause 7. The system of clause 1, wherein the system includes a menu navigation module configured to navigate hierarchical content based on swipe directions.
Clause 8. The system of clause 1, further comprising a display configured to render a video overlay illustrating a visual cue of the detected gesture in real-time.
Clause 9. The system of clause 1, wherein the gesture recognition operates without providing visual feedback to the user.
Clause 10. The system of clause 1, wherein the processor is configured to interpret a swipe gesture across a defined number of targets on a screen to access subcategories or content items.
Clause 11. The system of clause 1, wherein the swipe gestures control a digital interface selected from the group consisting of: an industrial machine, an automotive infotainment system, a smart home appliance, or a virtual reality environment.
Clause 12. The system of clause 1, wherein the gesture-based control system is configured to operate in real-time with less than 200 milliseconds of latency between gesture input and command execution.
Clause 13. The system of clause 1, wherein the field of view of the camera comprises a continuous gesture recognition zone not limited to predefined spatial boundaries.
Clause 14. The system of clause 1, wherein the gesture-based control system is configured to support both a gesture feedback mode and a gesture-only mode without visual indicators.
Clause 15. The system of clause 1, wherein the gesture input comprises a binary motion selected from forward, backward, up, or down.
Clause 16. The system of clause 1, wherein the processor is configured to detect the presence of multiple hands and process each hand's gesture independently; and wherein the processor is configured to continuously update a gesture model based on environmental feedback or additional training data.
Clause 17. The system of clause 1, wherein the system provides audible or haptic confirmation of detected input commands; and wherein the system is adapted to operate under variable lighting and background conditions through dynamic contrast or edge-detection enhancements applied to the real-time image data.
Clause 18. The system of clause 1, wherein the digital interface includes a content selection system that organizes media or data into a category and subcategory hierarchy navigable via swipe gestures.
Clause 19. A computer-implemented method for controlling a digital interface using gesture recognition, the method comprising: capturing, using a camera, a sequence of real-time image frames comprising a user's hand within a field of view; processing, by a processor, the image frames using a machine learning model trained to detect and classify hand gestures by comparing features of the captured hand images to a plurality of stored hand image models; determining, from the classified gesture, a positional attribute comprising at least one of a hand orientation, handedness, or motion vector; mapping the classified gesture to a predefined input command based on a direction of movement selected from the group consisting of a swipe left, swipe right, swipe up, or swipe down; and executing, in response to the mapped input command, an action in the digital interface corresponding to content navigation or system control.
Clause 20. A non-transitory computer-readable medium storing instructions that, when executed by one or more processors, cause a computing system to perform a method comprising: receiving real-time image data from a camera capturing a user's hand gesture; analyzing the image data using a machine learning-based gesture classification module that compares the image data against a set of pre-trained hand gesture models; determining a gesture type and associated attributes including handedness and directionality of movement; mapping the gesture type to a corresponding input command for a digital interface, wherein the input command is selected from the group consisting of: navigation forward, navigation backward, select content category, or reset menu; and triggering the corresponding input command to interact with the digital interface, wherein the interaction comprises at least one of content selection, application control, or hierarchical navigation.

When introducing elements of the present disclosure or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements.

Although this invention has been described with a certain degree of particularity, it is to be understood that the present disclosure has been made only by way of illustration and that numerous changes in the details of construction and arrangement of parts may be resorted to without departing from the spirit and the scope of the invention.

What is claimed is:

1. A gesture-based control system comprising:
a camera configured to capture real-time image data of a user's hand;
a processor operatively coupled to the camera, the processor configured to:
apply one or more machine learning models to the image data to detect a hand and identify one or more gestures based on a comparison with one or more stored hand image models;
determine a position, orientation, or handedness of the detected hand within a field of view of the camera; and
map the identified gesture to a corresponding input command for controlling a digital interface;
wherein the input command comprises a swipe-based command selected from the group consisting of a left swipe, a right swipe, an upward swipe, or a downward swipe.

2. The system of claim 1, wherein the processor is further configured to distinguish between a left-hand gesture and a right-hand gesture to generate differentiated input commands.

3. The system of claim 1, wherein the plurality of stored hand image models includes hand images in multiple orientations, lighting conditions, and backgrounds.

4. The system of claim 1, wherein the camera is integrated into a laptop, tablet, smart display, or mobile device.

5. The system of claim 1, wherein the gesture is identified as a static gesture selected from the group consisting of a “thumbs up,” “thumbs down,” or a “stop” gesture.

6. The system of claim 1, wherein the processor is further configured to determine whether a thumb and forefinger are touching in the image data.

7. The system of claim 1, wherein the system includes a menu navigation module configured to navigate hierarchical content based on swipe directions.

8. The system of claim 1, further comprising a display configured to render a video overlay illustrating a visual cue of the detected gesture in real-time.

9. The system of claim 1, wherein the gesture recognition operates without providing visual feedback to the user.

10. The system of claim 1, wherein the processor is configured to interpret a swipe gesture across a defined number of targets on a screen to access subcategories or content items.

11. The system of claim 1, wherein the swipe gestures control a digital interface selected from the group consisting of: an industrial machine, an automotive infotainment system, a smart home appliance, or a virtual reality environment.

12. The system of claim 1, wherein the gesture-based control system is configured to operate in real-time with less than 200 milliseconds of latency between gesture input and command execution.

13. The system of claim 1, wherein the field of view of the camera comprises a continuous gesture recognition zone not limited to predefined spatial boundaries.

14. The system of claim 1, wherein the gesture-based control system is configured to support both a gesture feedback mode and a gesture-only mode without visual indicators.

15. The system of claim 1, wherein the gesture input comprises a binary motion selected from forward, backward, up, or down.

16. The system of claim 1, wherein the processor is configured to detect the presence of multiple hands and process each hand's gesture independently; and
wherein the processor is configured to continuously update a gesture model based on environmental feedback or additional training data.

17. The system of claim 1, wherein the system provides audible or haptic confirmation of detected input commands; and
wherein the system is adapted to operate under variable lighting and background conditions through dynamic contrast or edge-detection enhancements applied to the real-time image data.

18. The system of claim 1, wherein the digital interface includes a content selection system that organizes media or data into a category and subcategory hierarchy navigable via swipe gestures.

19. A computer-implemented method for controlling a digital interface using gesture recognition, the method comprising:
capturing, using a camera, a sequence of real-time image frames comprising a user's hand within a field of view;
processing, by a processor, the image frames using a machine learning model trained to detect and classify hand gestures by comparing features of the captured hand images to a plurality of stored hand image models;
determining, from the classified gesture, a positional attribute comprising at least one of a hand orientation, handedness, or motion vector;
mapping the classified gesture to a predefined input command based on a direction of movement selected from the group consisting of a swipe left, swipe right, swipe up, or swipe down; and
executing, in response to the mapped input command, an action in the digital interface corresponding to content navigation or system control.

20. A non-transitory computer-readable medium storing instructions that, when executed by one or more processors, cause a computing system to perform a method comprising:
receiving real-time image data from a camera capturing a user's hand gesture;
analyzing the image data using a machine learning-based gesture classification module that compares the image data against a set of pre-trained hand gesture models;
determining a gesture type and associated attributes including handedness and directionality of movement;
mapping the gesture type to a corresponding input command for a digital interface, wherein the input command is selected from the group consisting of: navigation forward, navigation backward, select content category, or reset menu; and
triggering the corresponding input command to interact with the digital interface, wherein the interaction comprises at least one of content selection, application control, or hierarchical navigation.
